(19) United States
(12) Patent Application Publication
(10) Pub. No.: US 2021/0355344 A1
(43) Pub. Date: Nov. 18, 2021

(54) EPOXY RESIN COMPOSITION FOR ENCAPSULATING SEMICONDUCTOR DEVICE AND SEMICONDUCTOR DEVICE ENCAPSULATED USING THE SAME

(71) Applicant: SAMSUNG SDI CO., LTD., Yongin-si (KR)

(72) Inventors: Jin Min CHEON, Suwon-si (KR); Young Joon LEE, Suwon-si (KR); Seung Woo HONG, Suwon-si (KR)

(21) Appl. No.: 17/318,031

(22) Filed: May 12, 2021

(30) Foreign Application Priority Data
May 14, 2020 (KR) 10-2020-0058008

(51) Int. Cl. C09D 163/00

(52) U.S. Cl. CPC C09D 163/00; C08K 3/22

(57) ABSTRACT

An epoxy resin composition for encapsulation of semiconductor devices and a semiconductor device encapsulated using the same, the epoxy resin composition including an epoxy resin; a curing agent; and an inorganic filler, wherein the inorganic filler includes gadolinium oxide, samarium oxide, boron nitride, or boron carbide.

### CROSS-REFERENCE TO RELATED APPLICATION

Korean Patent Application No. 10-2020-0058008, filed on May 14, 2020 in the Korean Intellectual Property Office, and entitled: “Epoxy Resin Composition for Encapsulating Semiconductor Device and Semiconductor Device Encapsulated Using the Same,” is incorporated by reference herein in its entirety.

### BACKGROUND

### 1. Field

Embodiments relate to an epoxy resin composition for encapsulation of semiconductor devices and a semiconductor device encapsulated using the same.

### 2. Description of the Related Art

As a method of packaging semiconductor devices, such as ICs and LSIs, and obtaining a semiconductor apparatus, transfer molding of an epoxy resin composition may be attractive due to low expense and suitability for mass production. In addition, properties of semiconductor devices, such as reliability, may be enhanced through improvement of an epoxy resin or a phenolic resin as a curing agent.

### SUMMARY

The embodiments may be realized by providing an epoxy resin composition for encapsulation of semiconductor devices, the epoxy resin composition including an epoxy resin; a curing agent; and an inorganic filler, wherein the inorganic filler includes gadolinium oxide, samarium oxide, boron nitride, or boron carbide.

The gadolinium oxide, samarium oxide, boron nitride, or boron carbide may have an average particle diameter (D₅₀) of about 1 μm to about 50 μm.

The gadolinium oxide, samarium oxide, boron nitride, or boron carbide may be present in an amount of about 10 wt % to about 95 wt %, based on a total weight of the epoxy resin composition.

The inorganic filler may further include silica.

A weight ratio of the gadolinium oxide, samarium oxide, boron nitride, or boron carbide to the silica may range from about 9:1 to about 1:9.

The inorganic filler may include at least two of gadolinium oxide, samarium oxide, boron nitride, and boron carbide.

The epoxy resin composition may include about 0.5 wt % to about 20 wt % of the epoxy resin; about 0.1 wt % to about 13 wt % of the curing agent; and about 70 wt % to about 95 wt % of the inorganic filler, all wt % being based on a total weight of the epoxy resin composition.

The embodiments may be realized by providing a semiconductor device encapsulated using the epoxy resin composition for encapsulation of semiconductor devices according to an embodiment.

The gadolinium oxide, samarium oxide, boron nitride, or boron carbide may have an average particle diameter (D₅₀) of about 1 μm to about 50 μm.

The gadolinium oxide, samarium oxide, boron nitride, or boron carbide may be present in an amount of about 10 wt % to about 95 wt %, based on a total weight of the epoxy resin composition.

The inorganic filler may further include silica.

A weight ratio of the gadolinium oxide, samarium oxide, boron nitride, or boron carbide to the silica may range from about 9:1 to about 1:9.

The inorganic filler may include at least two of gadolinium oxide, samarium oxide, boron nitride, and boron carbide.

The epoxy resin composition may include about 0.5 wt % to about 20 wt % of the epoxy resin; about 0.1 wt % to about 13 wt % of the curing agent; and about 70 wt % to about 95 wt % of the inorganic filler, all wt % being based on a total weight of the epoxy resin composition.

### DETAILED DESCRIPTION

As used herein, the singular forms “a”, “an”, and “the” are intended to include the plural forms as well, unless the context clearly indicates otherwise. As used herein, the term “or” is not an exclusive term, e.g., “A or B” would include A, B, or A and B.

It will be further understood that the terms “comprises,” “comprising,” “includes,” and “including,” when used in this specification, specify the presence of stated features, integers, steps, operations, elements, components, and/or groups thereof, but do not preclude the presence or addition of one or more other features, integers, steps, operations, elements, components, or groups thereof.

Further, a numerical value related to a certain component is construed to include a tolerance range in interpretation of components, unless clearly stated otherwise.

As used herein to represent a specific numerical range, the expression “a to b” means “≥a and ≤b”.

As used herein, “average particle diameter (D₅₀)” is a typical particle diameter measure known in the art and refers to a particle diameter corresponding to 50% by volume in a volume cumulative distribution of particles.

In accordance with an embodiment, an epoxy resin composition for encapsulation of semiconductor devices may include, e.g., an epoxy resin; a curing agent; and an inorganic filler. In an implementation, the inorganic filler may include, e.g., gadolinium oxide, samarium oxide, boron nitride, or boron carbide.

Now, each component of the epoxy resin composition for encapsulation of semiconductor devices (hereinafter also referred to as an “epoxy resin composition”) will be described in more detail.

Epoxy Resin

The epoxy resin may include a suitable epoxy resin for encapsulation of semiconductor devices. In an implementation, the epoxy resin may include an epoxy compound containing at least two epoxy groups per molecule. Examples of the epoxy resin may include epoxy resins obtained by epoxidating a condensate of hydroxybenzaldehyde and phenols or alkyl phenols, phenol aralkyl epoxy resins, phenol novolac epoxy resins, cresol novolac epoxy resins, polyfunctional epoxy resins, naphthol novolac epoxy resins, bisphenol A/bisphenol F/bisphenol AD novolac epoxy resins, bisphenol A/bisphenol F/bisphenol AD glycidyl ethers, bishydroxybiphenyl epoxy resins, dicyclopentadiene epoxy resins, and biphenyl epoxy resins.

The epoxy resin may have an epoxy equivalent of about 100 g/eq to about 500 g/eq, in consideration of curability of the epoxy resin composition. Within this range, the degree of cure of the epoxy resin composition can be increased.

The epoxy resins listed above may be used alone or in combination thereof. In an implementation, the epoxy resin may be used in the form of an adduct, such as a melt master batch, prepared by pre-reacting the epoxy resin with other components including the curing agent, a curing accelerator, a release agent, a coupling agent, and a stress reliever.

In an implementation, the epoxy resin may be present in an amount of about 0.5 wt % to about 20 wt %, based on a total weight of the epoxy resin composition. Within this range, reduction in curability of the epoxy resin composition can be prevented. In an implementation, the epoxy resin may be present in an amount of about 3 wt % to about 15 wt % in the epoxy resin composition. In an implementation, the epoxy resin may be present in an amount of about 0.5 wt %, 0.6 wt %, 0.7 wt %, 0.8 wt %, 0.9 wt %, 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, 19 wt %, or 20 wt %, based on the total weight of the epoxy resin composition.

Curing Agent

The curing agent may include a suitable curing agent for encapsulation of semiconductor devices. Examples of the curing agent may include phenolic curing agents. Examples of the phenolic curing agents may include polyhydric phenol compounds including phenol aralkyl resins, phenol novolac resins, polyfunctional phenol resins, Xylok phenol resins, cresol novolac phenol resins, naphthol phenol resins, terpene phenol resins, dicyclopentadiene phenol resins, novolac phenol resins synthesized from bisphenol A and resol, tris(hydroxyphenyl)methane, and dihydroxybiphenyl. In an implementation, the curing agent may be a polyfunctional phenol resin.

The curing agent may have a hydroxyl equivalent of about 90 g/eq to about 250 g/eq, in consideration of curability of the epoxy resin composition. Within this range, the degree of cure of the epoxy resin composition can be increased.

The curing agents listed above may be used alone or in combination thereof. In an implementation, the curing agent may be used in the form of an adduct, such as a melt master batch, prepared by pre-reacting the curing agent with other components including the epoxy resin, a curing accelerator, a release agent, and a stress reliever.

In an implementation, the curing agent may be present in an amount of about 0.1 wt % to about 13 wt %, based on the total weight of the epoxy resin composition. Within this range, reduction in curability of the epoxy resin composition can be prevented. In an implementation, the curing agent may be present in an amount of about 1 wt % to about 10 wt % in the epoxy resin composition. In an implementation, the curing agent may be present in an amount of about 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, 5 wt %, 6 wt %, 7 wt %, 8 wt %, 9 wt %, 10 wt %, 11 wt %, 12 wt %, or 13 wt %, based on the total weight of the epoxy resin composition.

A mixing ratio of the epoxy resin and the curing agent may vary depending on requirements such as mechanical properties in a package and moisture resistance reliability. In an implementation, a chemical equivalent ratio of the epoxy resin to the curing agent may range from about 0.95 to about 3. Within this range, the epoxy resin composition may exhibit good strength after curing. In an implementation, a chemical equivalent ratio of the epoxy resin to the curing agent may range from about 1 to about 2. In an implementation, a chemical equivalent ratio of the epoxy resin to the curing agent may range from about 1 to about 1.75. In an implementation, a chemical equivalent ratio of the epoxy resin to the curing agent may be about 0.95, 0.96, 0.97, 0.98, 0.99, 1, 1.1, 1.2, 1.3, 1.4, 1.5, 1.6, 1.7, 1.8, 1.9, 2, 2.1, 2.2, 2.3, 2.4, 2.5, 2.6, 2.7, 2.8, 2.9, or 3.

Inorganic Filler

The epoxy resin composition according to an embodiment may include, e.g., gadolinium oxide, samarium oxide, boron nitride, or boron carbide, as the inorganic filler. These compounds have a high cross-section for neutron capture. Accordingly, when a semiconductor device is encapsulated with the epoxy resin composition including these compounds, semiconductor package-level neutron capture may be achieved.

In an implementation, the inorganic filler may include at least two of gadolinium oxide, samarium oxide, boron nitride, and boron carbide. These different compounds may absorb neutrons in different energy ranges, respectively. Accordingly, when the epoxy resin composition includes at least two of these compounds, the epoxy resin composition may absorb neutrons over extended energy ranges, thereby exhibiting further improved neutron shielding properties.

In an implementation, the gadolinium oxide, samarium oxide, boron nitride, and boron carbide may have a suitable shape, e.g., a spherical particle shape, a flake particle shape, or an amorphous particle shape.

The size of gadolinium oxide, samarium oxide, boron nitride, or boron carbide may vary depending on desired properties. In an implementation, the gadolinium oxide, samarium oxide, boron nitride, or boron carbide may have an average particle diameter (D₅₀) of, e.g., about 1 μm to about 50 μm, about 2 μm to about 30 μm, or about 3 μm to about 20 μm. Within this range, the epoxy resin composition may have good neutron shielding properties.

The amount of gadolinium oxide, samarium oxide, boron nitride, or boron carbide may vary depending on desired properties. In an implementation, the gadolinium oxide, samarium oxide, boron nitride, or boron carbide may be present in an amount of, e.g., about 10 wt % to about 95 wt %, about 20 wt % to about 80 wt %, or about 30 wt % to about 70 wt %, based on the total weight of the epoxy resin composition. Within this range, the epoxy resin composition may have good neutron shielding properties. In an implementation, the gadolinium oxide, samarium oxide, boron nitride, or boron carbide may be present in an amount of about 10 wt %, 11 wt %, 12 wt %, 13 wt %, 14 wt %, 15 wt %, 16 wt %, 17 wt %, 18 wt %, 19 wt %, 20 wt %, 21 wt %, 22 wt %, 23 wt %, 24 wt %, 25 wt %, 26 wt %, 27 wt %, 28 wt %, 29 wt %, 30 wt %, 31 wt %, 32 wt %, 33, wt % 34 wt %, 35 wt %, 36 wt %, 37 wt %, 38 wt %, 39 wt %, 40 wt %, 41 wt %, 42 wt %, 43 wt %, 44 wt %, 45 wt %, 46 wt %, 47 wt %, 48 wt %, 49 wt %, 50 wt %, 51 wt %, 52 wt %, 53 wt %, 54 wt %, 55 wt %, 56 wt %, 57 wt %, 58 wt %, 59 wt %, 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, 90 wt %, 91 wt %, 92 wt %, 93 wt %, 94 wt %, or 95 wt %, based on the total weight of the epoxy resin composition.

In an implementation, in addition to the gadolinium oxide, samarium oxide, boron nitride, or boron carbide, the inorganic filler may further include silica, e.g., fused silica, to help improve warpage resistance of a cured product of the epoxy resin composition. Herein, “fused silica” refers to amorphous silica having a true specific gravity of about 2.3 or less, and includes amorphous silica that is obtained by melting crystalline silica or synthesized from various raw materials. The shape and particle diameter of the silica may be a suitable shape and particle diameter. In an implementation, the silica may include a mixture of: about 50 wt % to about 99 wt % of spherical silica having an average particle diameter of about 5 μm to about 30 μm; and about 1 wt % to about 50 wt % of spherical silica having an average particle diameter of about 0.001 μm to 1 μm. In an implementation, the maximum particle diameter of the silica may be adjusted to one of about 45 μm, 55 μm, and 75 μm, as desired.

When the inorganic fillers further include the silica, the amount of the silica may vary depending on desired properties. In an implementation, a weight ratio of the gadolinium oxide, samarium oxide, boron nitride, or boron carbide to the silica in the epoxy resin composition may range from about 9:1 to about 1:9. In an implementation, the gadolinium oxide, samarium oxide, boron nitride, or boron carbide and the silica may be included in different amounts. Within this range, the inorganic filler may help further improve warpage resistance of a cured product of the epoxy resin composition. In an implementation, a weight ratio of the gadolinium oxide, samarium oxide, boron nitride, or boron carbide to the silica in the epoxy resin composition may range from about 9:1 to about 8:2. In an implementation, a weight ratio of the gadolinium oxide, samarium oxide, boron nitride, or boron carbide to the silica in the epoxy resin composition may range from about 7:3 to about 3:7.

The amount of the inorganic filler may vary depending on desired physical properties, such as formability, low stress, and strength at high temperatures. In an implementation, the inorganic filler may be present in an amount of about 70 wt % to about 95 wt %, based on the total weight of the epoxy resin composition. Within this range, it is possible to help secure flame retardancy, fluidity, and reliability of the epoxy resin composition. In an implementation, the inorganic filler may be present in an amount of about 80 wt % to about 95 wt % in the epoxy resin composition. In an implementation, the inorganic fillers may be present in an amount of about 85 wt % to about 95 wt %. In an implementation, the inorganic fillers may be present in an amount of about 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, 90 wt %, 91 wt %, 92 wt %, 93 wt %, 94 wt %, or 95 wt %, based on the total weight of the epoxy resin composition.

In an implementation, the epoxy resin composition may further include a curing accelerator.

Curing Accelerator

Herein, the curing accelerator may refer to a substance that promotes reaction between the epoxy resin and the curing agent. Examples of the curing accelerator may include tertiary amines, organometallic compounds, organophosphorus compounds, imidazole compounds, and boron compounds.

Examples of the tertiary amines may include benzyldimethylamine, triethanolamine, triethylenediamine, diethylaminoethanol, tri(dimethylaminomethyl)phenol, 2-2-(dimethylaminomethyl)phenol, 2,4,6-tris(diaminomethyl)phenol, tri-2-ethylhexylate, and the like. Examples of the organometallic compounds may include chromium acetylacetonate, zinc acetylacetonate, nickel acetylacetonate, and the like. Examples of the organophosphorus compounds may include tris-4-methoxyphosphine, tetrabutylphosphonium bromide, tetraphenylphosphonium bromide, phenylphosphine, diphenylphosphine, triphenylphosphine, triphenylphosphine triphenylborane, triphenylphosphine-1,4-benzoquinone adducts, and the like. Examples of the imidazole compounds may include 2-phenyl-4-methylimidazole, 2-methylimidazole, 2-phenylimidazole, 2-aminoimidazole, 2-methyl-1-vinylimidazole, 2-ethyl-4-methylimidazole, 2-heptadecylimidazole, and the like. Examples of the boron compounds may include tetraphenylphosphonium-tetraphenylborate, triphenylphosphine tetraphenylborate, tetraphenylboron salt, trifluoroborane-n-hexylamine, trifluoroborane monoethylamine, tetrafluoroborane triethylamine, tetrafluoroborane amine, and the like. In addition to these compounds, the curing accelerator may include, e.g., 1,5-diazabicyclo[4.3.0]non-5-ene (DBN), (1,8-diazabicyclo[5.4.0]undec-7-ene (DBU), a phenol novolac resin salt, or the like.

In an implementation, the curing accelerator may be used in the form of an adduct prepared by pre-reacting the curing accelerator with the epoxy resin or the curing agent.

In an implementation, the curing accelerator may be present in an amount of about 0.01 wt % to about 2 wt %, based on the total weight of the epoxy resin composition. Within this range, the curing accelerator can promote curing of the composition while increasing the degree of cure of the composition. In an implementation, the curing accelerator may be present in an amount of about 0.02 wt % to about 1.5 wt % in the epoxy resin composition.

In an implementation, the curing accelerator may be present in an amount of about 0.01 wt %, 0.02 wt %, 0.03 wt %, 0.04 wt %, 0.05 wt %, 0.06 wt %, 0.07 wt %, 0.08 wt %, 0.09 wt %, 0.1 wt %, 0.2 wt %, 0.3 wt %, 0.4 wt %, 0.5 wt %, 0.6 wt %, 0.7 wt %, 0.8 wt %, 0.9 wt %, 1 wt %, 1.1 wt %, 1.2 wt %, 1.3 wt %, 1.4 wt %, 1.5 wt %, 1.6 wt %, 1.7 wt %, 1.8 wt %, 1.9 wt %, or 2 wt % in the epoxy resin composition.

In an implementation, the epoxy resin composition may further include a coupling agent, a release agent, or a coloring agent.

Coupling Agent

The coupling agent may help increase interfacial strength between the epoxy resin and the inorganic filler through reaction with the epoxy resin and the inorganic filler, and may include, e.g., a silane coupling agent. The silane coupling agent may include a suitable silane coupling agent that can help increase interfacial strength between the epoxy resin and the inorganic filler through reaction with the epoxy resin and the inorganic fillers. Examples of the silane coupling agent may include epoxy silane, amino silane, ureido silane, mercapto silane, and alkyl silane. These may be used alone or in combination thereof.

In an implementation, the coupling agent may be present in an amount of about 0.01 wt % to about 5 wt %, based on the total weight of the epoxy resin composition. Within this range, a cured product of the composition may have increased strength. In an implementation, the coupling agent may be present in an amount of about 0.05 wt % to about 3 wt % in the epoxy resin composition.

For example, the coupling agent may be present in an amount of about 0.01 wt %, 0.02 wt %, 0.03 wt %, 0.04 wt %, 0.05 wt %, 0.06 wt %, 0.07 wt %, 0.08 wt %, 0.09 wt %, 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, or 5 wt %, based on the total weight of the epoxy resin composition.

Release Agent

The release agent may include, e.g., paraffin wax, ester wax, higher fatty acid, metallic salts of higher fatty acid, natural fatty acid, or metallic salts of natural fatty acid.

In an implementation, the release agent may be present in an amount of, e.g., about 0.01 wt % to about 1 wt %, in the epoxy resin composition. In an implementation, the release agent may be present in an amount of about 0.01 wt %, 0.02 wt %, 0.03 wt %, 0.04 wt %, 0.05 wt %, 0.06 wt %, 0.07 wt %, 0.08 wt %, 0.09 wt %, 0.1 wt %, 0.2 wt %, 0.3 wt %, 0.4 wt %, 0.5 wt %, 0.6 wt %, 0.7 wt %, 0.8 wt %, 0.9 wt %, or 1 wt %, based on the total weight of the epoxy resin composition.

Coloring Agent

The coloring agent may be used for laser marking of a semiconductor device encapsulant, and may include a suitable coloring agent. In an implementation, the coloring agent may include, e.g., among carbon black, titanium black, titanium nitride, dicopper hydroxide phosphate, iron oxide, or mica.

In an implementation, the coloring agent may be present in an amount of, e.g., about 0.01 wt % to about 5 wt % in the epoxy resin composition for encapsulation of semiconductor devices. In an implementation, the coloring agent may be present in an amount of about 0.05 wt % to about 3 wt %.

In an implementation, the coloring agent may be present in an amount of about 0.01 wt %, 0.02 wt %, 0.03 wt %, 0.04 wt %, 0.05 wt %, 0.06 wt %, 0.07 wt %, 0.08 wt %, 0.09 wt %, 0.1 wt %, 0.2 wt %, 0.3 wt %, 0.4 wt %, 0.5 wt %, 0.6 wt %, 0.7 wt %, 0.8 wt %, 0.9 wt %, 1 wt %, 2 wt %, 3 wt %, 4 wt %, or 5 wt % in the epoxy resin composition.

In an implementation, the epoxy resin composition may further include: an antioxidant such as tetrakis[methylene-3-(3,5-di-tertbutyl-4-hydroxyphenyl)propionate]methane; or a flame retardant such as aluminum hydroxide, without undesirably altering the effects of the composition, as desired.

The epoxy resin composition may be prepared through a process in which the aforementioned components are uniformly and sufficiently mixed in a predetermined mixing ratio using, e.g., a Henschel mixer or a Lodige mixer, followed by melt-kneading using a roll mill or a kneader, and then the resultant may be subjected to cooling and pulverization, thereby obtaining a final powder product.

The epoxy resin composition for encapsulation of semiconductor devices may be usefully applied to semiconductor devices, e.g., semiconductor devices mounted on mobile displays or automotive fingerprint sensors. Encapsulation of a semiconductor device with the epoxy resin composition may be generally performed by low-pressure transfer molding. In an implementation, encapsulation of a semiconductor device with the epoxy resin composition may also be performed by injection molding, casting, or the like.

In accordance with another embodiment, there is provided a semiconductor device encapsulated using the epoxy resin composition for encapsulation of semiconductor devices as set forth above.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

Details of components used in Examples and Comparative Examples were as follows:

(A) Epoxy resin: HP-4770 (DIC Corporation)

(B) Curing agent: MEH 7500-3S (Meiwa Corporation)

(C) Inorganic fillers

(c1) Gadolinium oxide (Gd₂O₃, D₅₀: 10 μm, low a particle)

(c2) Samarium oxide (Sm₂O₃, D₅₀: 5.2 μm, low a particle)

(c3) Boron nitride (BN, D₅₀: 10 μm, low a particle)

(c4) Boron carbide (B₄C, D₅₀: 4.6 μm, low a particle)

(c5) Silica (SiO₂, D₅₀: 8.6 μm, low a particle)

(D) Curing accelerator: TPP-k (Hokko Chemical)

(E) Coupling agent: SZ-6070 (Dow Corning Corporation)

(F) Release agent: Carnauba wax

Examples 1 to 6 and Comparative Example 1

The aforementioned components were weighed according to the compositions shown in Table 1 and then mixed together, thereby preparing an epoxy resin composition for encapsulation of semiconductor devices. In Table 1, the amount of each component is based on percent by weight of a corresponding composition.

TABLE 1

| | | Example | | | | | | Comparative |
|---|---|---|---|---|---|---|---|---|
| | | 1 | 2 | 3 | 4 | 5 | 6 | Example 1 |
| (A) | | 12.8 | 12.8 | 12.8 | 12.8 | 12.8 | 12.8 | 12.8 |
| (B) | | 6.2 | 6.2 | 6.2 | 6.2 | 6.2 | 6.2 | 6.2 |
| (C) | (c1) | 10 | — | — | — | — | — | — |
| | (c2) | — | 30 | 50 | — | — | 25 | — |
| | (c3) | — | — | — | 50 | — | — | — |
| | (c4) | — | — | — | — | 50 | 25 | — |
| | (c5) | 70 | 50 | 30 | 30 | 30 | 30 | 80 |
| (D) | | 0.4 | 0.4 | 0.4 | 0.4 | 0.4 | 0.4 | 0.4 |
| (E) | | 0.4 | 0.4 | 0.4 | 0.4 | 0.4 | 0.4 | 0.4 |
| (F) | | 0.2 | 0.2 | 0.2 | 0.2 | 0.2 | 0.2 | 0.2 |

Property Evaluation

(1) Spiral flow (unit: inch): Using a low pressure transfer molding machine, each of the epoxy resin compositions prepared in Examples 1 to 6 and Comparative Example 1 was injected into a mold for measurement of spiral flow according to EMMI-1-66 under conditions of a mold temperature of 175° C., a load of 70 kgf/cm², an injection pressure of 9 MPa, and a curing time of 90 seconds, followed by measurement of flow length.

(2) Shrinkage (unit: %): Using a transfer molding press, each of the epoxy resin compositions prepared in Examples 1 to 6 and Comparative Example 1 was molded in an ASTM mold for preparation of a flexural strength specimen at a temperature of 175° C. under a load of 70 kgf/cm², thereby obtaining a molded specimen (125 mm×12.6 mm×6.4 mm). Then, the obtained specimen was placed in an oven at 175° C. and then subjected to post-molding curing (PMC) for 600 seconds, followed by cooling, and then the length of the specimen was measured with a caliper. A shrinkage rate was calculated according to Equation 1:

Shrinkage (%)=(length of mold at 175° C.−length of specimen)÷(length of mold at 175° C.)×100

(3) Glass transition temperature (Tg, unit: ° C.): Glass transition temperature was measured using a thermomechanical analyzer (TMA). Here, the TMA was set to heat a specimen from 25° C. to 300° C. at a heating rate of 10° C./minute.

(4) Neutron shielding rate (unit: %): Neutron shielding capability was evaluated by neutron radioactivation analysis that measures and analyzes the radiation dose of radioactive isotopes generated by neutron reactions, under the following conditions:
Neutron source: 5W research reactor
Energy level of incident neutrons: 0 MeV to 10 MeV (neutrons having an energy level of 1 eV or less: neutrons having an energy level of 10 MeV or more=4:1)
Neutron fluence (neutrons/cm² sec): 7.8×10⁸

TABLE 2

| | Example | | | | | | Comparative |
|---|---|---|---|---|---|---|---|
| | 1 | 2 | 3 | 4 | 5 | 6 | Example 1 |
| Spiral flow | 75 | 74 | 70 | 60 | 50 | 60 | 80 |
| (inch @175° C.) | | | | | | | |
| Shrinkage | 0.26 | 0.27 | 0.27 | 0.28 | 0.30 | 0.29 | 0.25 |
| (%@175° C. × | | | | | | | |
| 600 s) | | | | | | | |
| Tg (° C.) | 165 | 164 | 165 | 165 | 162 | 158 | 160 |
| Neutron | 10.1 | 46.5 | 61.5 | 51.2 | 57.4 | 64.8 | ND* |
| shielding | | | | | | | |
| rate (%) | | | | | | | |

*ND: not detected

From Table 2, it may be seen that the epoxy resin compositions of Examples 1 to 6, including gadolinium oxide, samarium oxide, boron nitride, or boron carbide as an inorganic filler, had good properties in terms of fluidity, shrinkage, and neutron shielding without reduction in Tg, as compared with the epoxy resin composition of Comparative Example 1, free from gadolinium oxide, samarium oxide, boron nitride, or boron carbide.

By way of summation and review, as integration of semiconductors is accelerated with reduction in size and weight and improvement in performance of electronic devices and demand for surface mounting of semiconductor devices increases, issues associated with typical epoxy resin compositions are arising.

In recent years, the frequency of occurrence of soft errors due to natural background radiation (cosmic rays) has increased rapidly with reduction in chip size and operating voltage. Therefore, neutron-induced defects of semiconductor devices in transit by air may be effectively reduced.

One or more embodiments may provide an epoxy resin composition for encapsulation of semiconductor devices, which can provide neutron shielding.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An epoxy resin composition for encapsulation of semiconductor devices, the epoxy resin composition comprising:
an epoxy resin;
a curing agent; and
an inorganic filler,
wherein the inorganic filler includes gadolinium oxide, samarium oxide, boron nitride, or boron carbide.

2. The epoxy resin composition as claimed in claim 1, wherein the gadolinium oxide, samarium oxide, boron nitride, or boron carbide has an average particle diameter (D₅₀) of about 1 μm to about 50 μm.

3. The epoxy resin composition as claimed in claim 1, wherein the gadolinium oxide, samarium oxide, boron nitride, or boron carbide is present in an amount of about 10 wt % to about 95 wt %, based on a total weight of the epoxy resin composition.

4. The epoxy resin composition as claimed in claim 1, wherein the inorganic filler further includes silica.

5. The epoxy resin composition as claimed in claim 4, wherein a weight ratio of the gadolinium oxide, samarium oxide, boron nitride, or boron carbide to the silica ranges from about 9:1 to about 1:9.

6. The epoxy resin composition as claimed in claim 1, wherein the inorganic filler includes at least two of gadolinium oxide, samarium oxide, boron nitride, and boron carbide.

7. The epoxy resin composition as claimed in claim 1, wherein the epoxy resin composition includes:
about 0.5 wt % to about 20 wt % of the epoxy resin;
about 0.1 wt % to about 13 wt % of the curing agent; and
about 70 wt % to about 95 wt % of the inorganic filler, all wt % being based on a total weight of the epoxy resin composition.

8. A semiconductor device encapsulated using the epoxy resin composition for encapsulation of semiconductor devices as claimed in claim 1.

9. The semiconductor device as claimed in claim 8, wherein the gadolinium oxide, samarium oxide, boron nitride, or boron carbide has an average particle diameter (D₅₀) of about 1 μm to about 50 μm.

10. The semiconductor device as claimed in claim 8, wherein the gadolinium oxide, samarium oxide, boron nitride, or boron carbide is present in an amount of about 10 wt % to about 95 wt %, based on a total weight of the epoxy resin composition.

11. The semiconductor device as claimed in claim 8, wherein the inorganic filler further includes silica.

12. The semiconductor device as claimed in claim 11, wherein a weight ratio of the gadolinium oxide, samarium oxide, boron nitride, or boron carbide to the silica ranges from about 9:1 to about 1:9.

13. The semiconductor device as claimed in claim 8, wherein the inorganic filler includes at least two of gadolinium oxide, samarium oxide, boron nitride, and boron carbide.

14. The semiconductor device as claimed in claim 8, wherein the epoxy resin composition includes:
about 0.5 wt % to about 20 wt % of the epoxy resin;
about 0.1 wt % to about 13 wt % of the curing agent; and
about 70 wt % to about 95 wt % of the inorganic filler, all wt % being based on a total weight of the epoxy resin composition.
